(19) United States
(12) Patent Application Publication
(10) Pub. No.: US 2016/0064408 A1
(43) Pub. Date: Mar. 3, 2016

(54) NONVOLATILE SEMICONDUCTOR MEMORY DEVICE

(71) Applicant: Kabushiki Kaisha Toshiba, Minato-ku (JP)

(72) Inventors: Masao SHINGU, Yokkaichi (JP); Masaaki HIGUCHI, Yokkaichi (JP); Katsuyuki SEKINE, Yokkaichi (JP); Kazuhiro MATSUO, Yokkaichi (JP)

(73) Assignee: Kabushiki Kaisha Toshiba, Minato-ku (JP)

(21) Appl. No.: 14/805,954

(22) Filed: Jul. 22, 2015

Related U.S. Application Data
(60) Provisional application No. 62/042,621, filed on Aug. 27, 2014.

(51) Int. Cl. H01L 27/115; H01L 29/51; H01L 29/423

(52) U.S. Cl. CPC H01L 27/11582; H01L 29/4234; H01L 29/517

(57) ABSTRACT

According to an embodiment, a nonvolatile semiconductor memory device comprises: a plurality of conductive layers stacked in a first direction via an inter-layer insulating layer; a semiconductor layer having the first direction as a longer direction; a tunnel insulating layer contacting a side surface of the semiconductor layer; a charge accumulation layer contacting a side surface of the tunnel insulating layer; and a block insulating layer contacting a side surface of the charge accumulation layer. The inter-layer insulating layer comprises: a first silicon oxide layer; a first metal oxide layer; and a first silicon nitride layer. The first metal oxide layer is formed on a first surface facing the conductive layer, of the first silicon oxide layer. The first silicon nitride layer is formed on the first surface via the first metal oxide layer.

### CROSS-REFERENCE TO RELATED APPLICATIONS

This application is based upon and claims the benefit of U.S. Provisional Patent Application No. 62/042,621, filed on Aug. 27, 2014, the entire contents of which are incorporated herein by reference.

### FIELD

Embodiments described here relate to a nonvolatile semiconductor memory device.

### BACKGROUND

### Description of the Related Art

A memory cell configuring a nonvolatile semiconductor memory device such as a NAND type flash memory includes a semiconductor layer, a control gate, and a charge accumulation layer. The memory cell changes its threshold voltage according to a charge accumulated in the charge accumulation layer to store a magnitude of this threshold voltage as data. In recent years, enlargement of capacity and raising of integration level has been proceeding in such a nonvolatile semiconductor memory device. Moreover, in order to raise integration level of the memory, a nonvolatile semiconductor memory device having the memory cells disposed three-dimensionally therein (a three-dimensional type semiconductor memory device) has been proposed.

### BRIEF DESCRIPTION OF THE DRAWINGS

FIG. 1 is a block diagram showing a schematic configuration of a nonvolatile semiconductor memory device according to a first embodiment.

FIG. 2 is a circuit diagram showing a configuration of part of the same nonvolatile semiconductor memory device.

FIG. 3 is a schematic perspective view showing a configuration of part of the same nonvolatile semiconductor memory device.

FIG. 4 is a schematic cross-sectional view showing a configuration of part of the same nonvolatile semiconductor memory device.

FIG. 5 is a schematic cross-sectional view showing a configuration of part of the same nonvolatile semiconductor memory device.

FIG. 6 is a cross-sectional view for explaining a simulation performed by the inventors.

FIG. 7 is a graph showing results of the same simulation.

FIG. 8 is a cross-sectional view showing a manufacturing process of the same nonvolatile semiconductor memory device.

FIG. 9 is a cross-sectional view showing a manufacturing process of the same nonvolatile semiconductor memory device.

FIG. 10 is a cross-sectional view showing a manufacturing process of the same nonvolatile semiconductor memory device.

FIG. 11 is a cross-sectional view showing a manufacturing process of the same nonvolatile semiconductor memory device.

FIG. 12 is a cross-sectional view showing a manufacturing process of the same nonvolatile semiconductor memory device.

FIG. 13 is a cross-sectional view showing a manufacturing process of the same nonvolatile semiconductor memory device.

FIG. 14 is a cross-sectional view showing a manufacturing process of the same nonvolatile semiconductor memory device.

FIG. 15 is a cross-sectional view showing a manufacturing process of the same nonvolatile semiconductor memory device.

FIG. 16 is a cross-sectional view showing a manufacturing process of the same nonvolatile semiconductor memory device.

FIG. 17 is a cross-sectional view showing a manufacturing process of the same nonvolatile semiconductor memory device.

FIG. 18 is a cross-sectional view showing a manufacturing process of the same nonvolatile semiconductor memory device.

FIG. 19 is a schematic cross-sectional view showing a configuration of part of a nonvolatile semiconductor memory device according to a second embodiment.

FIG. 20 is a schematic cross-sectional view showing a configuration of part of the same nonvolatile semiconductor memory device.

FIG. 21 is a cross-sectional view showing a manufacturing process of the same nonvolatile semiconductor memory device.

FIG. 22 is a cross-sectional view showing a manufacturing process of the same nonvolatile semiconductor memory device.

FIG. 23 is a cross-sectional view showing a manufacturing process of the same nonvolatile semiconductor memory device.

FIG. 24 is a cross-sectional view showing a manufacturing process of the same nonvolatile semiconductor memory device.

FIG. 25 is a cross-sectional view showing a manufacturing process of the same nonvolatile semiconductor memory device.

FIG. 26 is a cross-sectional view showing a manufacturing process of the same nonvolatile semiconductor memory device.

FIG. 27 is a schematic cross-sectional view showing a configuration of part of a nonvolatile semiconductor memory device according to a third embodiment.

FIG. 28 is a schematic cross-sectional view showing a configuration of part of the same nonvolatile semiconductor memory device.

### DETAILED DESCRIPTION

A nonvolatile semiconductor memory device according to an embodiment described below comprises: a plurality of conductive layers stacked in a first direction via an inter-layer insulating layer; a semiconductor layer having the first direction as a longer direction; a tunnel insulating layer contacting a side surface of the semiconductor layer; a charge accumulation layer contacting a side surface of the tunnel insulating layer; and a block insulating layer contacting a side surface of the charge accumulation layer. The inter-layer insulating layer comprises: a first silicon oxide layer; a first metal oxide layer; and a first silicon nitride layer. The first metal oxide layer is formed on a first surface facing the conductive layer, of the first silicon oxide layer. The first silicon nitride layer is formed on the first surface via the first metal oxide layer.

### FIRST EMBODIMENT

### Overall Configuration

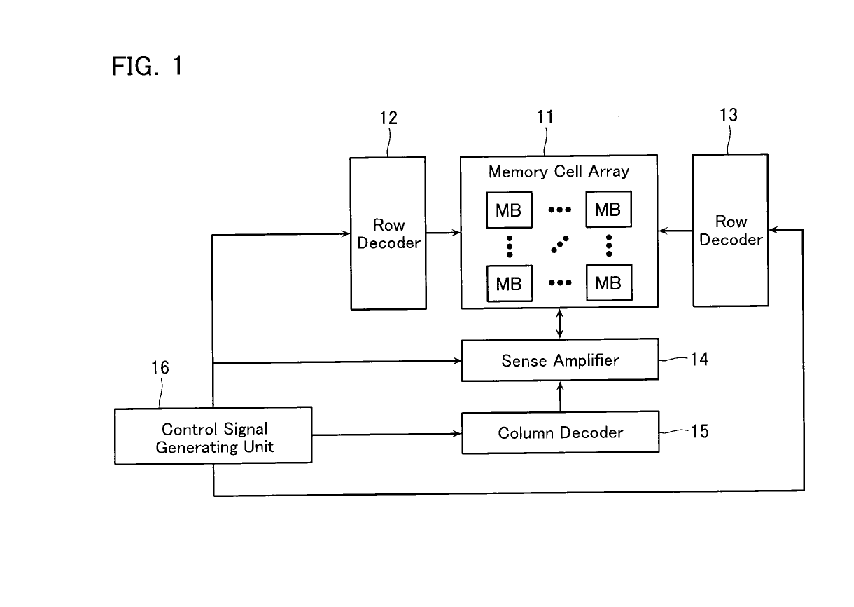

A configuration of a nonvolatile semiconductor memory device according to a first embodiment will be described below. FIG. 1 is a block diagram of the nonvolatile semiconductor memory device according to the first embodiment.

As shown in FIG. 1, the nonvolatile semiconductor memory device according to the first embodiment comprises: a memory cell array 11; row decoders 12 and 13 that control read and write of this memory cell array 11; a sense amplifier 14; a column decoder 15; and a control signal generating unit 16.

The memory cell array 11 is configured from a plurality of memory blocks MB. Each of the memory blocks MB includes a plurality of memory transistors MTr arranged three-dimensionally therein and each storing data in a nonvolatile manner. Moreover, the memory block MB configures a minimum erase unit of batch erase when executing a data erase operation. The memory transistors MTr are disposed in a matrix (three-dimensionally) in a row direction, a column direction, and a stacking direction.

As shown in FIG. 1, the row decoders 12 and 13 decode the likes of a down-loaded block address signal, and control the memory cell array 11. The sense amplifier 14 reads data from the memory cell array 11. The column decoder 15 decodes a column address signal and controls the sense amplifier 14. The control signal generating unit 16 boosts a reference voltage to generate a high voltage required during write or erase, and furthermore generates a control signal, and controls the row decoders 12 and 13, the sense amplifier 14, and the column decoder 15.

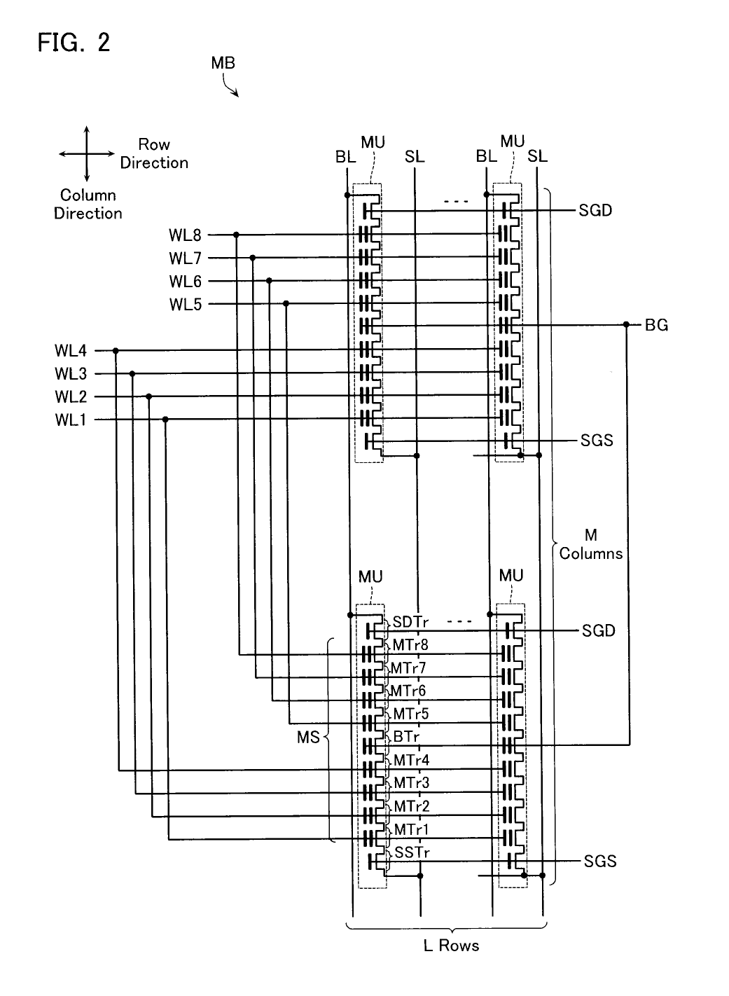

Next, a specific configuration of the memory block MB will be described with reference to FIG. 2. FIG. 2 is a circuit diagram for explaining the specific configuration of the memory block MB. The memory block MB includes a plurality of bit lines BL, a plurality of source lines SL, and a plurality of memory units MU connected to these bit lines BL and source lines SL.

The memory unit MU configures a NAND type flash memory, and is configured having a source side select transistor SSTr and a drain side select transistor SDTr respectively connected to both ends of a memory string MS, the memory string MS being configured from memory transistors MTr1 to MTr8 and a back gate transistor BTr connected in series. The memory transistors MTr1 to MTr8 change their threshold voltage by accumulating a charge in their charge accumulation layer, and store data corresponding to this threshold voltage.

Drains of the drain side select transistors SDTr of a plurality of the memory units MU aligned in the column direction are connected to a common bit line BL. Sources of the source side select transistors SSTr of a plurality of the memory units MU aligned in the column direction are connected to a common source line SL. Gates of each of the memory transistors MTr1 to MTr8 are respectively connected to word lines WL1 to WL8. A back gate line BG is commonly connected to gates of the back gate transistors BTr. A source side select gate line SGS is connected to gates of the source side select transistors SSTr, and a drain side select gate line SGD is connected to gates of the drain side select transistors SDTr.

### Memory Cell Array 11

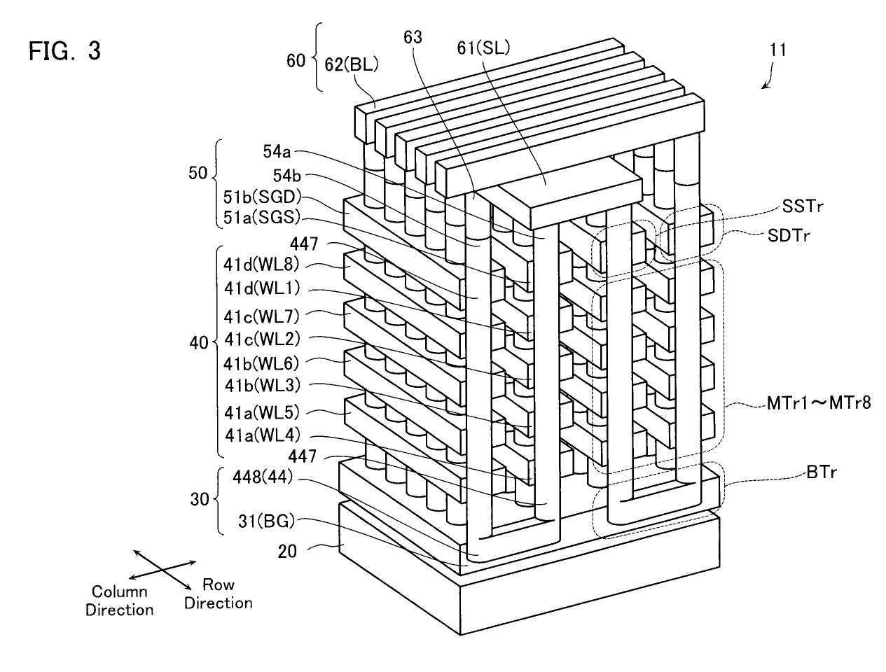

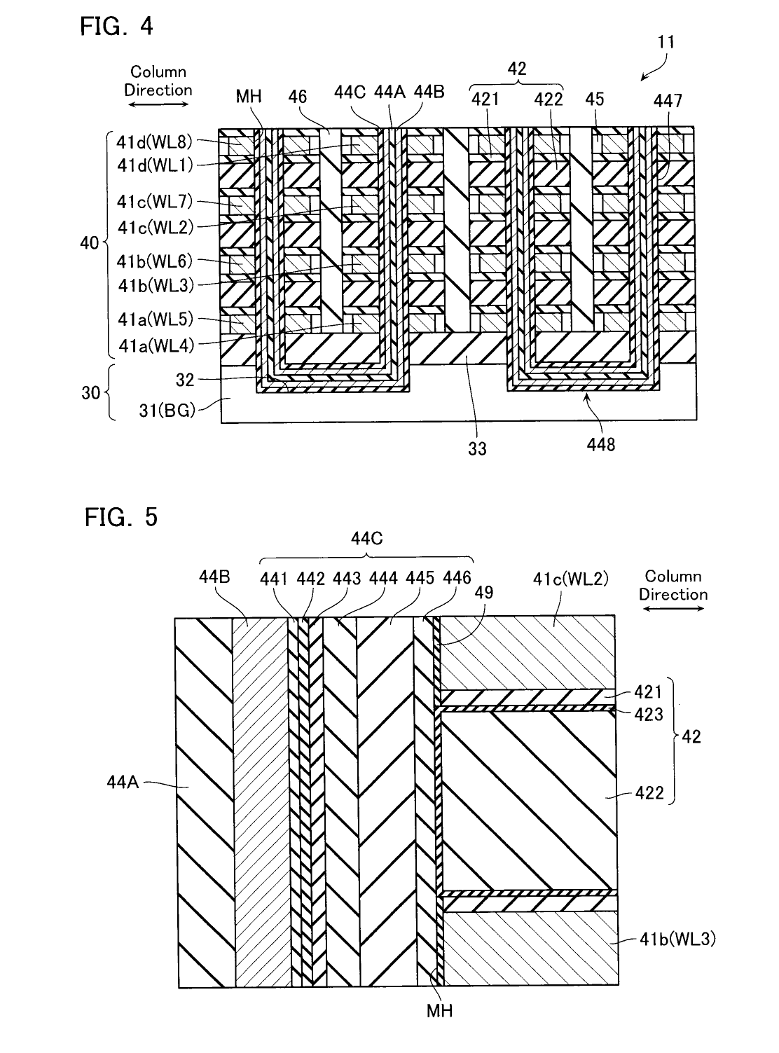

Next, a structure of the memory cell array 11 according to the first embodiment will be described with reference to FIGS. 3 to 5. FIG. 3 is a perspective view illustrating part of the memory cell array 11. FIG. 4 is a cross-sectional view illustrating part of the memory cell array 11. Moreover, FIG. 5 is an enlarged view of part of FIG. 4.

As shown in FIG. 3, the memory cell array 11 includes a back gate layer 30, a memory layer 40, a select transistor layer 50, and a wiring line layer 60 that are stacked sequentially on a substrate 20. The back gate layer 30 functions as the back gate transistor BTr. The memory layer 40 functions as the memory transistors MTr1 to MTr8. The select transistor layer 50 functions as the drain side select transistor SDTr and the source side select transistor SSTr. The wiring line layer 60 functions as the source line SL and the bit line BL.

As shown in FIG. 3, the back gate layer 30 includes a back gate conductive layer 31. The back gate conductive layer 31 functions as the back gate line BG and as the gate of the back gate transistor BTr. The back gate conductive layer 31 is formed so as to extend in a plate shape, two-dimensionally, in the row direction and the column direction parallel to the substrate 20. The back gate conductive layer 31 is formed by, for example, polysilicon (poly-Si).

As shown in FIG. 4, the back gate layer 30 includes aback gate hole 32. The back gate hole 32 is formed so as to dig in to the back gate conductive layer 31.

As shown in FIGS. 3 and 4, the memory layer 40 is formed in a layer above the back gate layer 30. The memory layer 40 includes four layers of word line conductive layers 41a to 41d. The word line conductive layer 41a functions as the word line WL4 and as the gate of the memory transistor MTr4. In addition, the word line conductive layer 41a functions as the word line WL5 and as the gate of the memory transistor MTr5. Similarly, the word line conductive layers 41b to 41d respectively function as the word lines WL1 to WL3 and WL6 to WL8 and as the gates of the memory transistors MTr1 to MTr3 and MTr6 to MTr8.

As shown in FIG. 4, above and below the word line conductive layers 41a to 41d, inter-layer insulating layers 42 are provided. The inter-layer insulating layer 42 includes a silicon oxide layer 422 and a silicon nitride layer 421 covering upper and lower surfaces of this silicon oxide layer 422. In addition, as shown in FIG. 5, a metal oxide layer 423 is formed between these silicon oxide layer 422 and silicon nitride layer 421. The metal oxide layer 423 is formed by a metal oxide of the likes of an aluminum oxide (AlOₓ) such as alumina (Al₂O₃), a hafnium oxide (HfOₓ), or a titanium oxide (TiOₓ), for example. Moreover, a film thickness of the metal oxide layer 423 is 1 nm or less, and preferably 0.1 nm to 0.5 nm.

The word line conductive layers 41a to 41d are disposed with a certain pitch in the column direction. Moreover, the word line conductive layers 41a to 41d are formed so as to extend having the row direction (a direction perpendicular to the plane of paper in FIG. 4) as a longer direction. The word line conductive layers 41a to 41d are configured by, for example, polysilicon (poly-Si).

As shown in FIG. 4, the memory layer 40 includes a memory hole MH. The memory hole MH is formed so as to penetrate the word line conductive layers 41a to 41d and the inter-layer insulating layer 42. The memory hole MH is formed so as to be aligned with close to an end in the column direction of the back gate hole 32. In addition, an oxide layer 49 is formed on surfaces exposed to the memory hole MH, of the word line conductive layers 41a to 41d and the silicon nitride layer 421.

Moreover, as shown in FIG. 4, the back gate layer 30 and the memory layer 40 include a memory core layer 44A, a memory semiconductor layer 44B, and a memory gate insulating layer 44C. The memory semiconductor layer 44B functions as a body (channel) of the memory string MS (memory transistors MTr1 to MTr8) and the back gate transistor BTr.

As shown in FIG. 5, the memory gate insulating layer 44C comprises, from a memory semiconductor layer 44B side to a side of a side surface of the memory hole MH: an ONO layer configured from an oxide layer 441, a nitride layer 442 and an oxide layer 443; a charge accumulation layer 444; a block insulating layer 445; and a cap insulating layer 446. The oxide layer 441, the oxide layer 443, and the block insulating layer 445 are formed from, for example, silicon oxide (SiO₂). In addition, the nitride layer 442, the charge accumulation layer 444, and the cap insulating layer 446 are formed from, for example, silicon nitride (SiN). Moreover, the charge accumulation layer 444 is configured capable of accumulating a charge.

As shown in FIG. 4, the memory core layer 44A, the memory semiconductor layer 44B, and the memory gate insulating layer 44C are formed so as to fill the back gate hole 32 and the memory hole MH. The memory core layer 44A, the memory semiconductor layer 44B, and the memory gate insulating layer 44C include a pair of columnar layers 447 extending in a direction perpendicular to the substrate 20, and a coupling layer 448 that couples lower ends of the pair of columnar layers 447, and are formed in a U shape as viewed from the row direction. The memory core layer 44A is formed from, for example, silicon oxide (SiO₂). Moreover, the memory semiconductor layer 44B is formed by, for example, polysilicon (poly-Si).

The above-described back gate layer 30 is formed so as to surround a side surface of the coupling layer 448. Moreover, the word line conductive layers 41a to 41d are formed so as to surround a side surface of the columnar layer 447.

In addition, as shown in FIG. 3, an upper portion of one of the columnar layers 447 connected to the coupling layer 448 is surrounded by a source side conductive layer 51a functioning as the source side select gate line SGS, and functions as a channel of the source side select transistor SSTr. Similarly, an upper portion of the other of the columnar layers 447 connected to the coupling layer 448 is surrounded by a drain side conductive layer 51b functioning as the drain side select gate line SGD, and functions as a channel of the drain side select transistor SDTr.

Furthermore, as shown in FIG. 3, one of the columnar layers 447 connected to the coupling layer 448 is connected to a source line layer 61 functioning as the source line SL. Moreover, the other of the columnar layers 447 connected to the coupling layer 448 is connected, via a plug layer 63, to a bit line layer 62 functioning as the bit line BL.

As shown in FIG. 5, in the nonvolatile semiconductor memory device according to the present embodiment, the inter-layer insulating layer 42 formed between the word lines WL comprises: the silicon oxide layer 422; the metal oxide layer 423 covering the upper and lower surfaces of the silicon oxide layer 422; and the silicon nitride layer 421 covering a surface facing the word line WL, of the metal oxide layer 423. As it will be mentioned in detail later, such a configuration results in insulation properties between the word lines WL being improved. Therefore, it is possible to achieve miniaturization of the nonvolatile semiconductor memory device while maintaining insulation properties between the word lines WL.

Note that in the inter-layer insulating layer 42 according to the present embodiment, the metal oxide layer 423 and the silicon nitride layer 421 are provided on both of the upper surface and lower surface of the silicon oxide layer 422. However, it is also possible for the metal oxide layer 423 and the silicon nitride layer 421 to be provided on only one of the upper surface and lower surface, for example.

Moreover, the memory core layer 44A, the memory semiconductor layer 44B, and the memory gate insulating layer 44C according to the present embodiment include the pair of columnar layers 447 extending in a direction perpendicular to the substrate 20, and the coupling layer 448 that couples lower ends of the pair of columnar layers 447, and are formed in a U shape as viewed from the row direction. However, it is also possible for the coupling layer 448 to be omitted and the memory core layer 44A, the memory semiconductor layer 44B, and the memory gate insulating layer 44C to be formed in an I shape, for example.

### Characteristics of Inter-Layer Insulating Layer 42

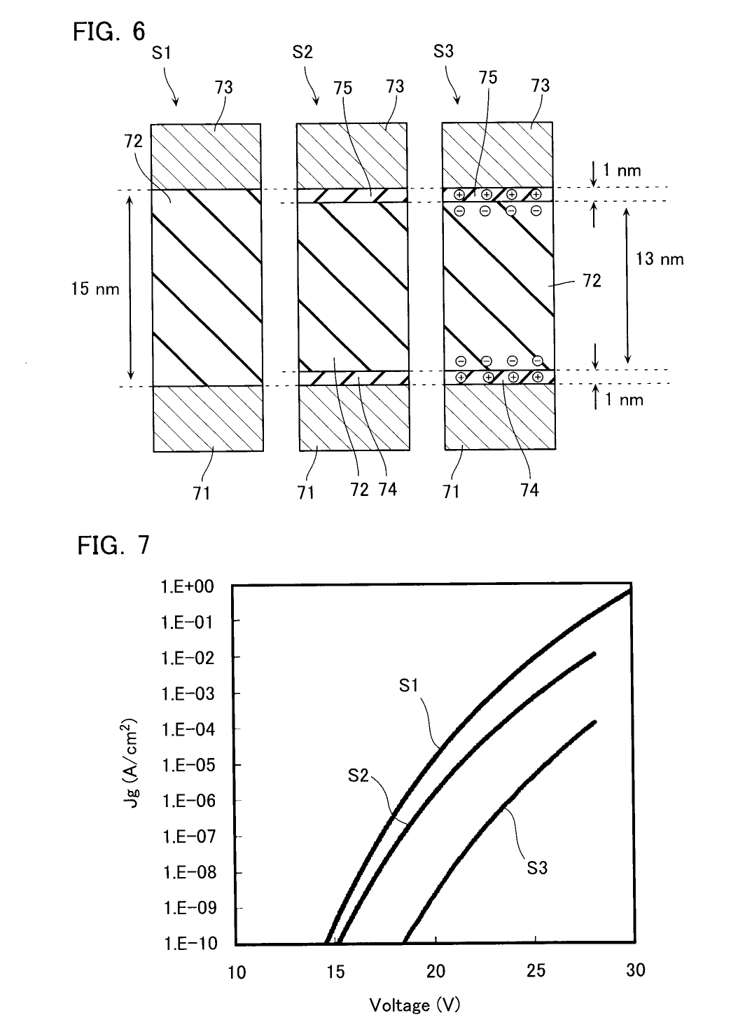

Next, in order to explain characteristics of the inter-layer insulating layer 42, results of a simulation performed by the inventors will be described with reference to FIGS. 6 and 7. FIG. 6 is a cross-sectional view for explaining sample models S1, S2, and S3 used by the inventors during the simulation. Moreover, FIG. 7 is a graph showing results of this simulation.

The sample models S1, S2, and S3 shown in FIG. 6 each have an insulating layer 72 formed between a pair of conductive layers 71 and 73, and film thicknesses of the insulating layer 72 are each similar.

As shown in FIG. 6, the sample model S1 has a configuration in which 15 nm of an insulating layer 72 configured from silicon oxide (SiO₂) is stacked on the conductive layer 71 whose work function is set to 4.05 eV, and in which the conductive layer 73 whose work function is set to 4.05 eV is further stacked thereon.

As shown in FIG. 6, the sample model S2 is configured substantially similarly to the sample model S1, but differs in that in the sample model S2, an insulating layer 74 and an insulating layer 75 that are configured from silicon nitride (SiN) are respectively formed between the conductive layer 71 and insulating layer 72 and between the insulating layer 72 and conductive layer 73. Note that in the sample model S2, a film thickness of the insulating layer 72 is 13 nm, and film thicknesses of the insulating layer 74 and insulating layer 75 are each 1 nm.

As shown in FIG. 6, the sample model S3 is configured substantially similarly to the sample model S2, but differs in that in the sample model S3, dipoles are formed between the insulating layer 74 and insulating layer 72 and between the insulating layer 72 and insulating layer 75, the insulating layer 74 and the insulating layer 75 are positively charged, and the insulating layer 72 is negatively charged.

The simulation was performed by calculating current density between the conductive layer 71 and the conductive layer 73 when a voltage was applied between the conductive layer 71 and the conductive layer 73, for these sample models S1 to S3.

FIG. 7 shows results of this simulation, the horizontal axis showing the voltage applied between the conductive layer 71 and the conductive layer 73, and the vertical axis showing current density Jg between the conductive layer 71 and the conductive layer 73.

As shown in FIG. 7, in all cases, the current density Jg increases in response to increase in the applied voltage. Moreover, as shown in FIG. 7, at least in a region where the applied voltage is about 15 V to 28 V, the current density of the sample model S2 is about 1/10 of the current density of the sample model S1. Furthermore, in this region, the current density of the sample model S3 is about 1/100 of that of the sample model S2 and about 1/1000 of that of the sample model S1.

Therefore, according to results of this simulation, it is possible to suitably insulate between the conductive layer 71 and the conductive layer 73 by stacking silicon nitride (SiN) between the conductive layer 71 and the conductive layer 73 and furthermore, by forming a dipole between the silicon nitride (SiN) and silicon oxide (SiO₂) such that a silicon oxide (SiO₂) side is a negative side.

Such an effect can be obtained when alumina (Al₂O₃) of 1 nm or less is deposited between the silicon oxide (SiO₂) and the silicon nitride (SiN). Specifically, leak current can be effectively reduced when a film thickness of the alumina is 0.1 nm to 0.5 nm. This is considered to be because by making the film thickness of the alumina smaller than 1 nm, the alumina itself did not function as an insulating layer and only a leak reduction effect due to the dipole could be obtained. Such polarization occurs even when the metal oxide between the silicon nitride and the silicon oxide is a metal oxide other than alumina, for example, a hafnium oxide.

### Method of Manufacturing

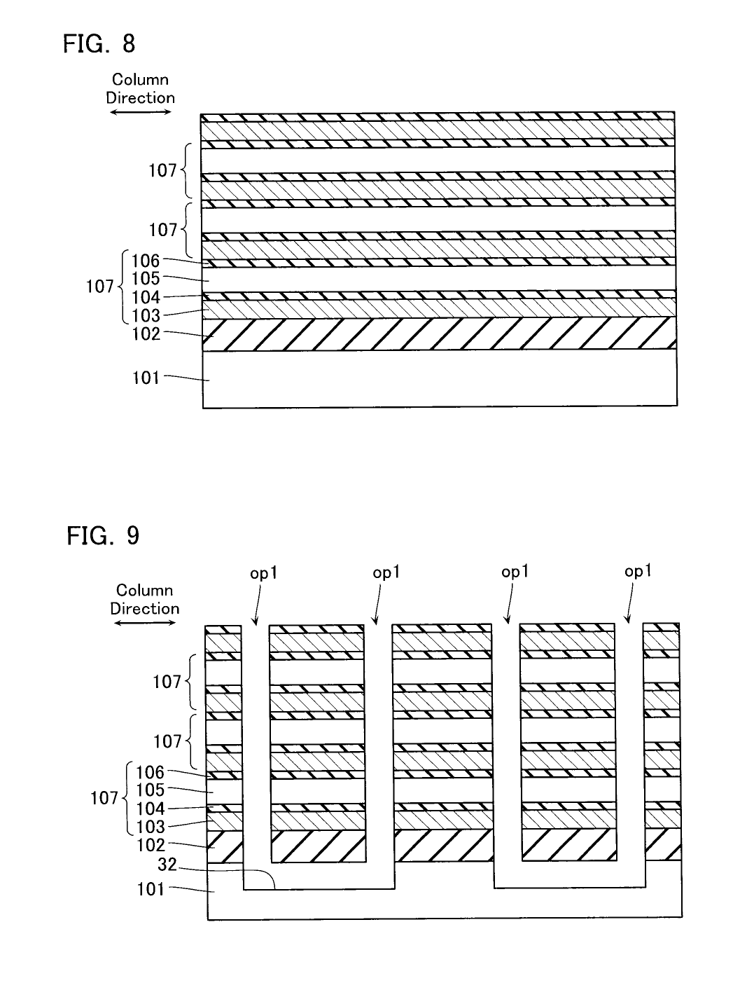

Next, a method of manufacturing the nonvolatile semiconductor memory device according to the present embodiment will be described with reference to FIGS. 8 to 18. FIGS. 8 to 18 are cross-sectional views for explaining the method of manufacturing the same nonvolatile semiconductor memory device.

As shown in FIG. 8, a conductive layer 101 and an insulating layer 102 are stacked on a substrate not illustrated, and a plurality of stacked bodies 107 each configured from a conductive layer 103, a diffusion prevention layer 104, a sacrifice layer 105, and a diffusion prevention layer 106, are stacked thereon. The conductive layer 101 and the conductive layer 103 are configured from, for example, silicon (Si) doped with boron (B). In addition, the insulating layer 102 is configured from, for example, silicon oxide (SiO₂). Moreover, the diffusion prevention layer 104 and the diffusion prevention layer 106 are configured from, for example, silicon nitride (SiN). Furthermore, the sacrifice layer 105 is configured from, for example, silicon (Si) not doped with boron (B).

Next, as shown in FIG. 9, an opening op1 penetrating each of the layers in the stacking direction is formed on the configuration shown in FIG. 8. The opening op1 is to become the memory hole MH shown in FIGS. 4 and 5.

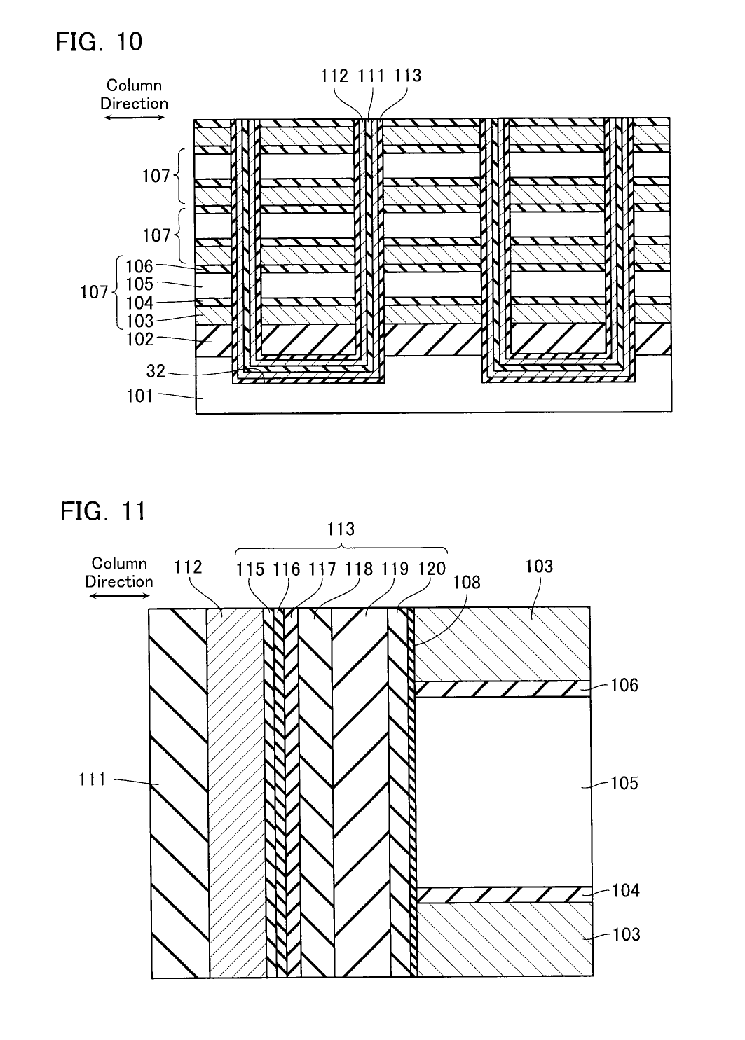

Next, as shown in FIGS. 10 and 11, a cap insulating layer 120 which is formed by, for example, silicon nitride (SiN) which is to become the cap insulating layer 446, a silicon oxide layer 119 which is to become the block insulating layer 445, a silicon nitride layer 118 which is to become the charge accumulation layer 444, a silicon oxide layer 117 which is to become the oxide layer 443, a silicon nitride layer 116 which is to become the nitride layer 442, and a silicon oxide layer 115 which is to become the oxide layer 441 are sequentially deposited in the opening op1 to form a Nitride-Oxide layer laminated body 113 which is to become the memory gate insulating layer 44C. At this time, natural oxidation occurs at portions facing the memory hole MH, of the conductive layer 103, the diffusion prevention layer 104, the sacrifice layer 105, and the diffusion prevention layer 106. Therefore, a memory hole oxide layer 108 is formed between the cap insulating layer 120 and the conductive layer 103, the diffusion prevention layer 104, the sacrifice layer 105, and the diffusion prevention layer 106 (refer to FIG. 11). Next, a polysilicon layer 112 which is to become the memory semiconductor layer 44B and a silicon oxide layer 111 which is to become the memory core layer 44A are formed inside the Nitride-Oxide layer laminated body 113. As a result, the opening op1 is filled, as shown in FIG. 10.

Note that when forming the Nitride-Oxide layer laminated body 113, the diffusion prevention layers 104 and 106 prevent boron in the conductive layer 103 from migrating to the sacrifice layer by thermal diffusion.

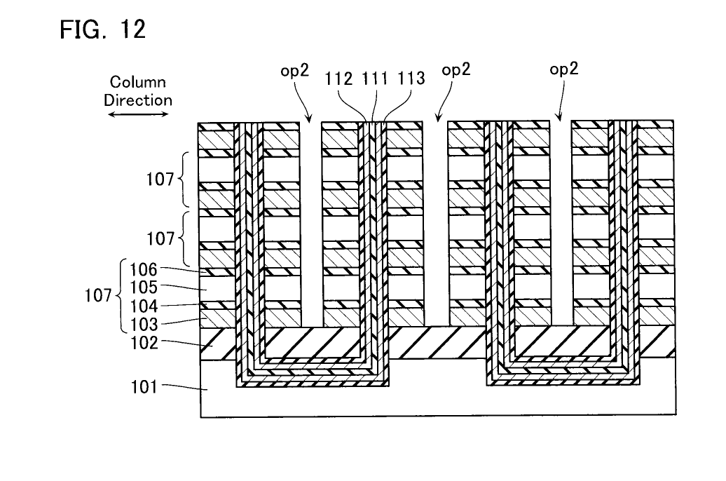

Next, as shown in FIG. 12, the stacked pluralities of conductive layers 103, diffusion prevention layers 104, sacrifice layers 105, and diffusion prevention layers 106 are divided in the column direction. A slit (trench) dividing these layers is referred to below as an opening op2. Formation of the opening op2 results in the plurality of conductive layers 103 being formed in a shape of the word line WL.

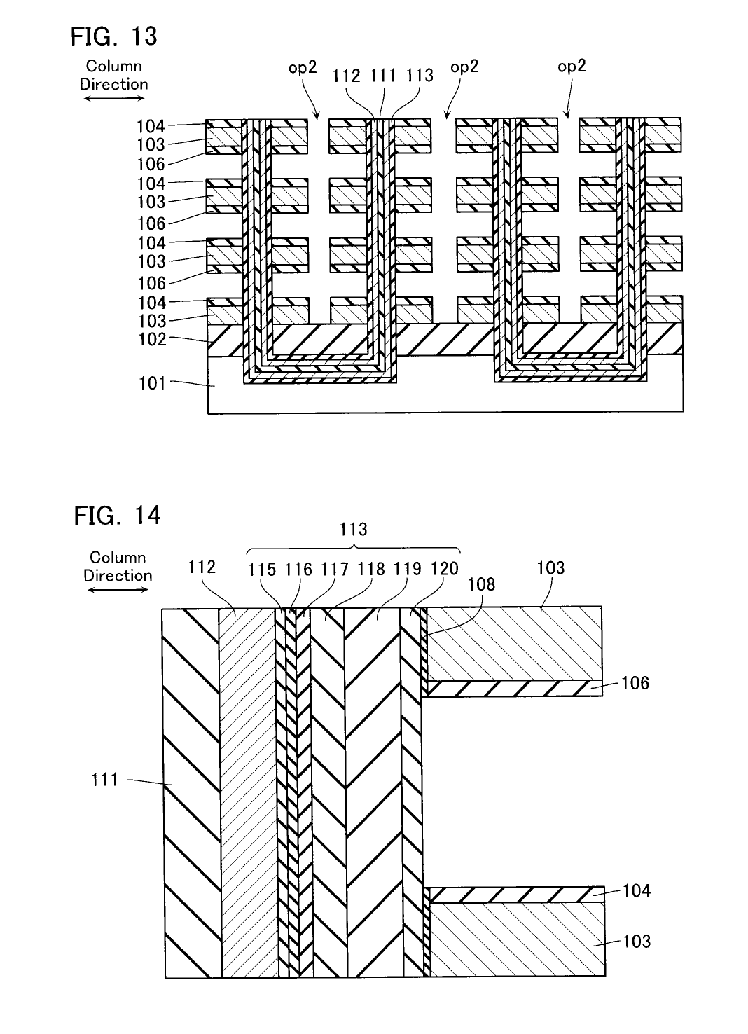

Next, as shown in FIGS. 13 and 14, the sacrifice layer 105 is removed via the opening op2. Now, the conductive layer 103 is configured from silicon doped with boron, and the sacrifice layer 105 is configured from silicon not doped with boron. When employing, for example, TMY (trimethyl(2-hydroxyethyl)ammonium hydroxide) as a chemical solution used in removal of the sacrifice layer 105, etching rate of silicon differs significantly according to content of boron, hence the chemical solution that has penetrated from the opening op2 selectively removes only the sacrifice layer 105. Note that in this process, a portion formed on a sidewall of the sacrifice layer 105, of the memory hole oxide layer 108 is removed, and a side surface of the cap insulating layer 120 is exposed.

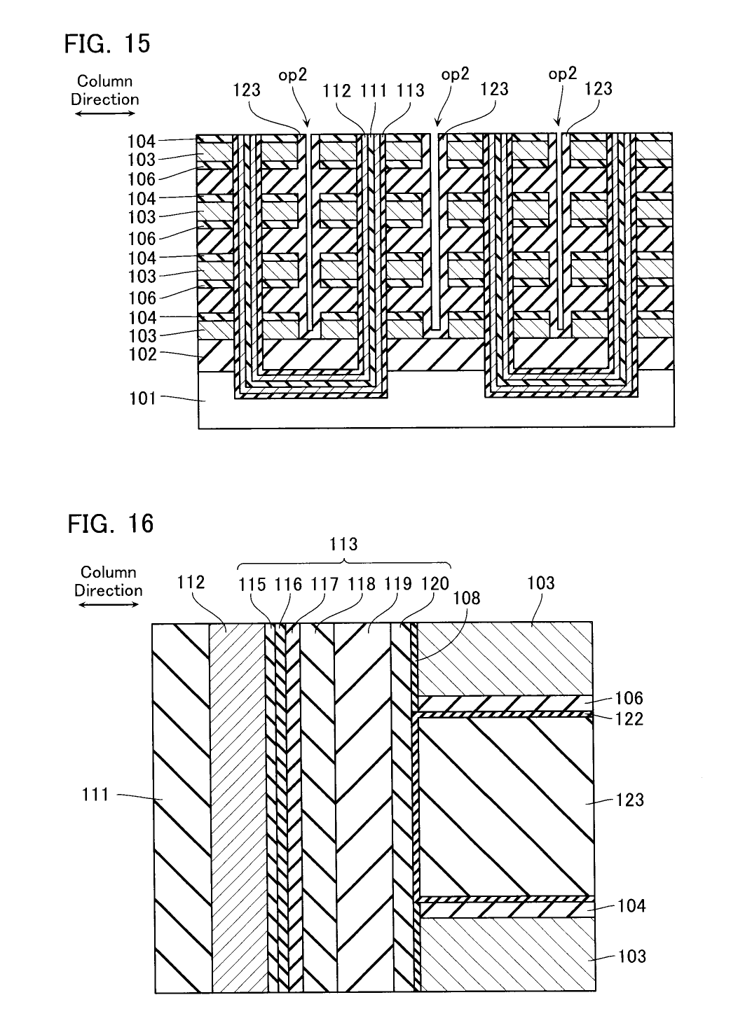

Next, as shown in FIGS. 15 and 16, an alumina layer 122 and a silicon oxide layer 123 are formed on an upper surface of the diffusion prevention layer 104, a side surface of the cap insulating layer 120, and a lower surface of the diffusion prevention layer 106, via the opening op2.

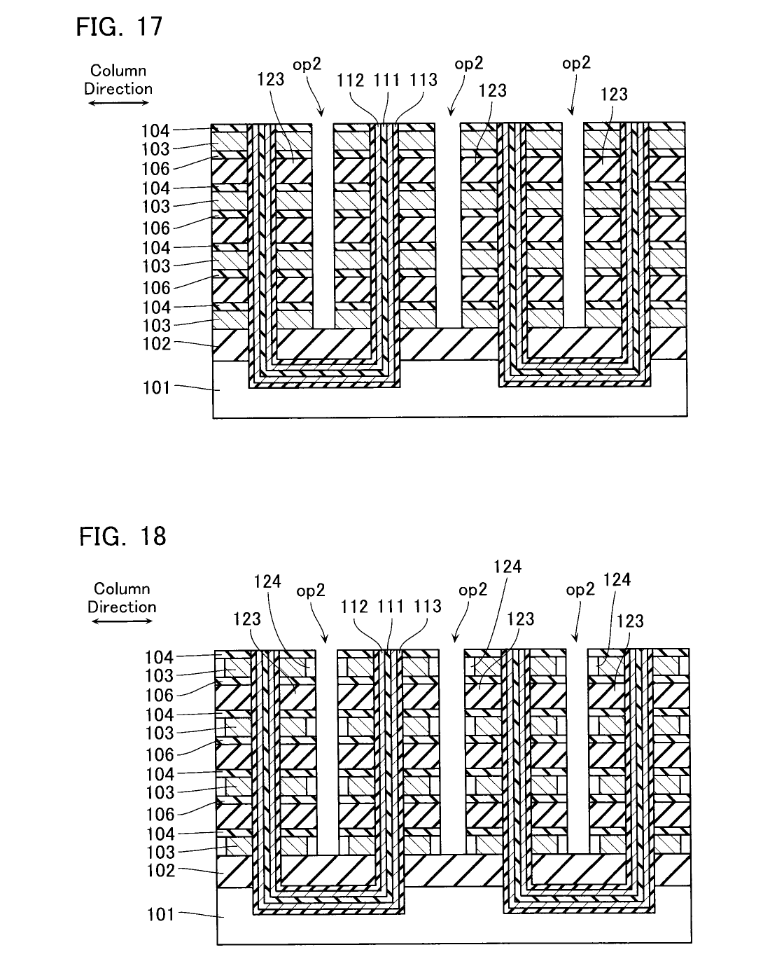

Next, as shown in FIG. 17, etching-back is performed, and the silicon oxide layer 123 formed on a sidewall of the conductive layer 103 is removed. At this time, the alumina layer 122 formed on the sidewall of the conductive layer 103 may be removed. Note that removal of the silicon oxide layer 123 and the alumina layer 122 is performed employing, for example, DHF (Diluted Hydrogen Fluoride) or chemical dry etching.

Next, as shown in FIG. 18, the conductive layer 103 undergoes siliciding by a siliciding process via the opening op2. As a result, resistivity of the conductive layer 103 lowers.

Then, an insulating layer 46 is filled in to the opening op2, whereby the nonvolatile semiconductor memory device of the kind shown in FIG. 4 is formed.

### SECOND EMBODIMENT

### Configuration

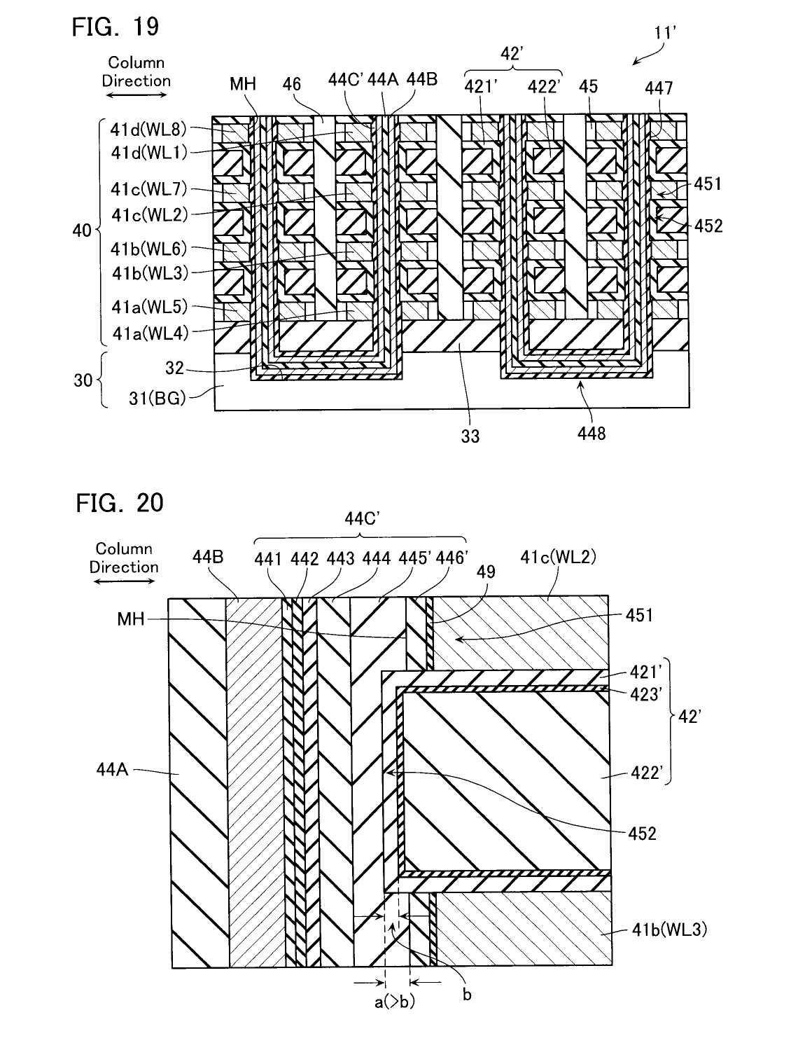

Next, a configuration of a nonvolatile semiconductor memory device according to a second embodiment will be described with reference to FIGS. 19 and 20. FIGS. 19 and 20 are cross-sectional views for explaining the configuration of the nonvolatile semiconductor memory device according to the second embodiment. Note that below, similar configurations to those of the first embodiment are assigned with similar reference symbols to those assigned in the first embodiment, and descriptions thereof will be omitted.

As shown in FIGS. 19 and 20, the nonvolatile semiconductor memory device according to the second embodiment is basically configured similarly to the nonvolatile semiconductor memory device according to the first embodiment, but differs in the following points.

That is, as shown in FIGS. 19 and 20, a recessed portion 452 which is more recessed compared to a portion facing the word line WL, of a block insulating layer 445′ is formed in a portion facing an inter-layer insulating layer 42′, of the block insulating layer 445′. Moreover, a protruding portion 451 which protrudes more compared to the recessed portion 452 is formed in the portion facing the word line WL, of the block insulating layer 445′. Furthermore, a cap insulating layer 446′ is divided in the stacking direction, and is formed only on a protruding portion 451 surface. Note that a size “a” of a level difference formed by the recessed portion 452 and the protruding portion 451 is larger than a film thickness “b” of a silicon nitride layer 421′.

Moreover, in the present embodiment, the inter-layer insulating layer 42′ contacts the recessed portion 452 of the block insulating layer 445′. In other words, the silicon nitride layer 421′ of the inter-layer insulating layer 42′ contacts the recessed portion 452 of the block insulating layer 445′.

The nonvolatile semiconductor memory device according to the present embodiment displays similar advantages to those of the nonvolatile semiconductor memory device according to the first embodiment.

Moreover, as will be mentioned later, the nonvolatile semiconductor memory device according to the present embodiment removes a silicon nitride layer contacting the conductive layer forming the word line WL, before implementing crystallization annealing of the memory semiconductor layer 44B. This makes it possible to suppress diffusion of boron from these conductive layers to silicon nitride during crystallization annealing and prevent resistance of the word line WL being raised due to lowering of boron concentration.

Furthermore, in the present embodiment, the size “a” of the level difference formed by the recessed portion 452 and the protruding portion 451 is larger than the film thickness “b” of the silicon nitride layer 421′. Therefore, it is possible to prevent a current path being formed between the word lines WL by silicon nitride whose resistivity is lower compared to that of silicon oxide, and thereby suitably insulate between the word lines WL.

### Method of Manufacturing

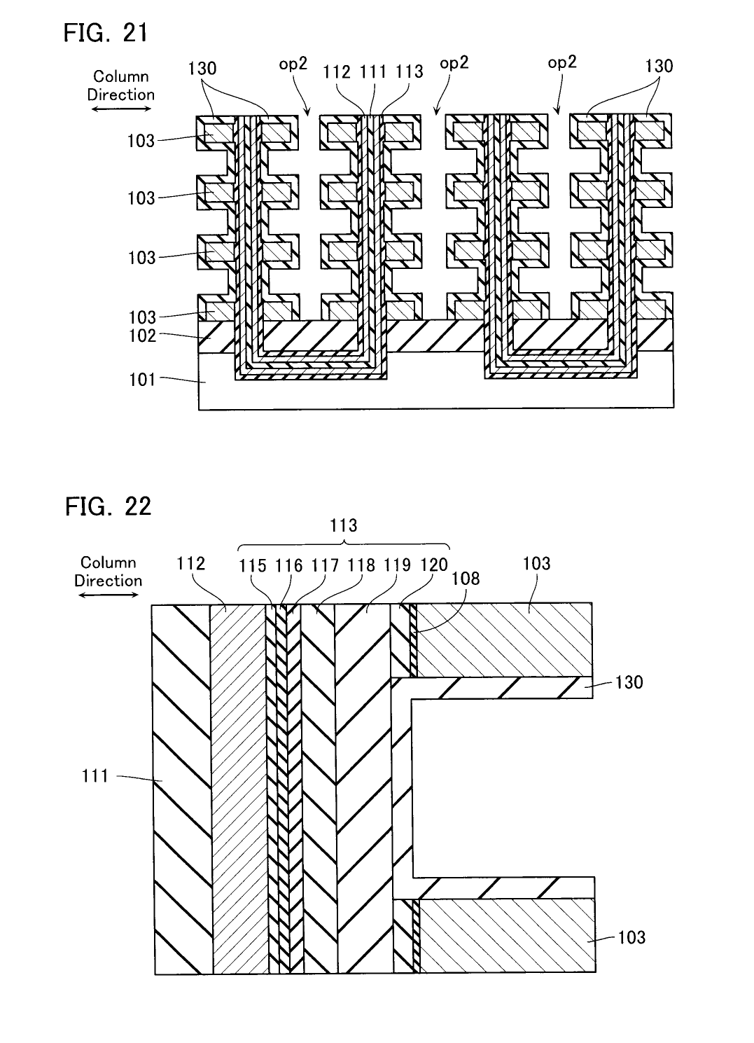

Next, a method of manufacturing the nonvolatile semiconductor memory device according to the present embodiment will be described with reference to FIGS. 21 to 26. FIGS. 21 to 26 are cross-sectional views for explaining the method of manufacturing the same nonvolatile semiconductor memory device.

The method of manufacturing the nonvolatile semiconductor memory device according to the present embodiment is performed similarly to the method of manufacturing according to the first embodiment up to the process described with reference to FIGS. 13 and 14.

Next, as shown in FIGS. 21 and 22, oxidation is performed. As a result, a portion facing the opening op2, of the cap insulating layer 120, and portions facing the opening op2, of the diffusion prevention layer 104, the diffusion prevention layer 106, and the conductive layer 103 are oxidized, and an oxide layer 130 is formed. Moreover, along with this, the cap insulating layer 120 is divided in the stacking direction.

Next, crystallization annealing is performed, and crystallization of the polysilicon layer 112 is performed. The crystallization annealing is performed at, for example, 850° C. to 1080° C. At this time, the conductive layer 103 is covered by the oxide layer 130 and by the memory hole oxide layer 108 formed by natural oxidation, and does not contact silicon nitride. Therefore, it is possible to prevent boron diffusing from the conductive layer 103 to silicon nitride during annealing.

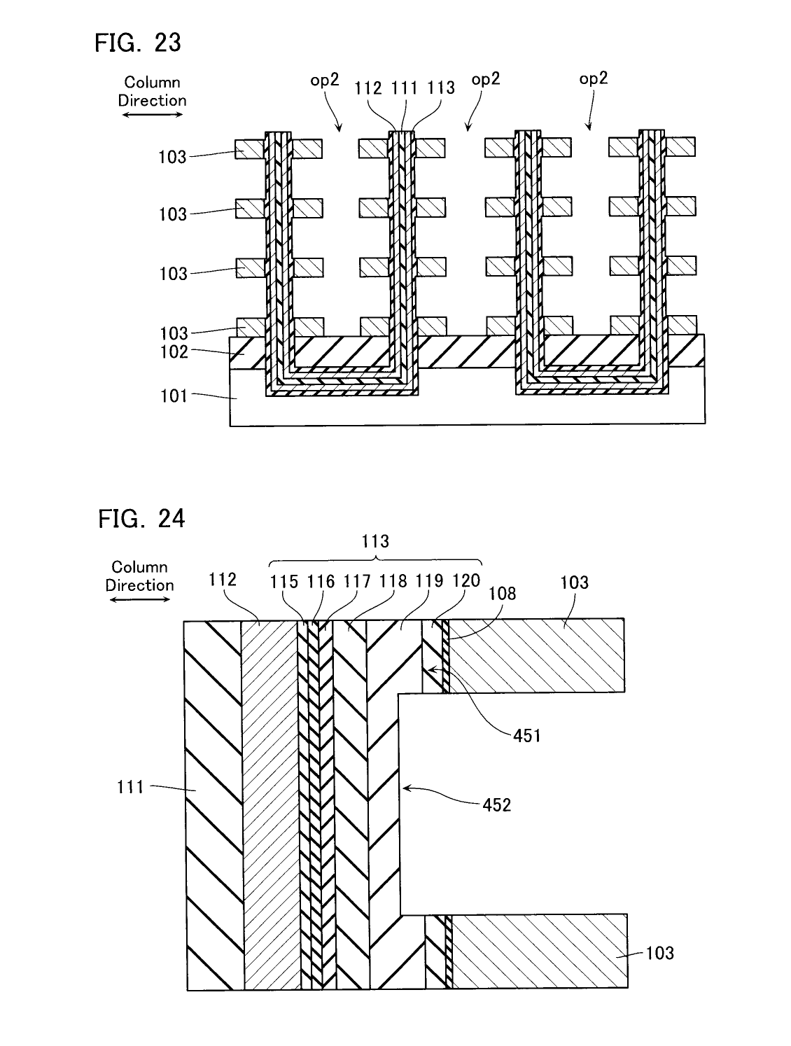

Next, as shown in FIGS. 23 and 24, etching is performed via the opening op2, and the oxide layer 130 is removed. Moreover, part of the silicon oxide layer 119 is removed, and the recessed portion 452 and protruding portion 451 are formed in the silicon oxide layer 119. Note that removal of the oxide layer 130 and the silicon oxide layer 119 is performed employing, for example, DHF (Diluted Hydrogen Fluoride) or chemical dry etching.

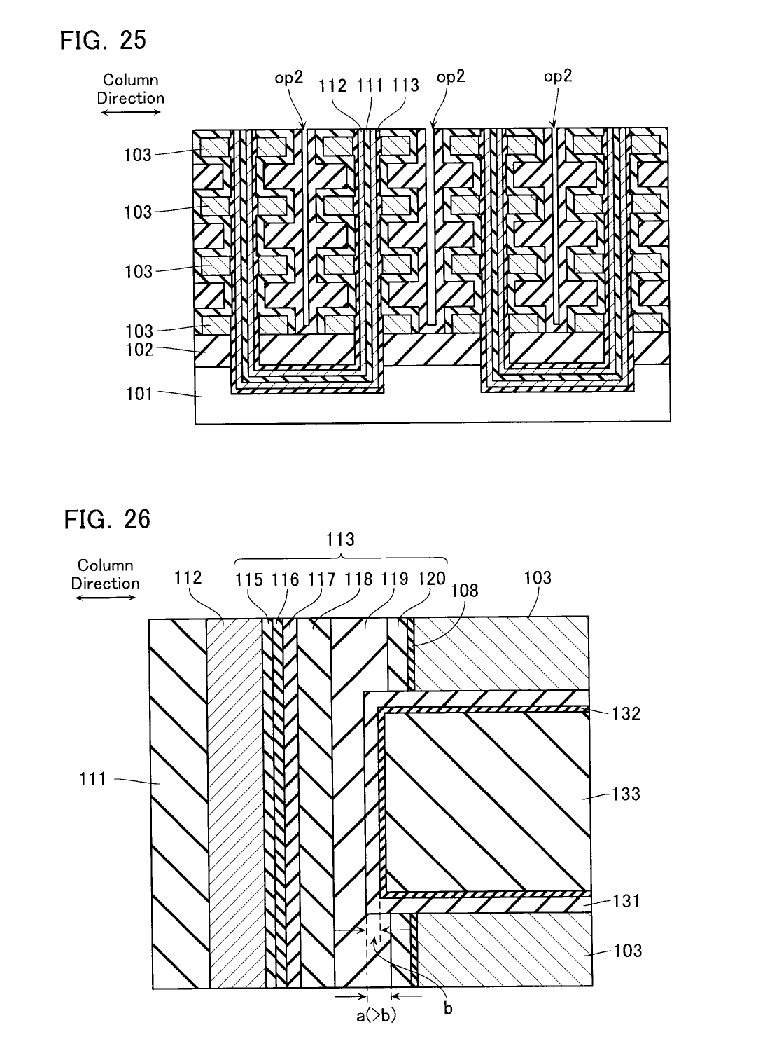

Next, as shown in FIGS. 25 and 26, a silicon nitride layer 131, an alumina layer 132, and a silicon oxide layer 133 are formed on upper surfaces and lower surfaces of the conductive layer 103 and of the cap insulating layer 120 divided in the stacking direction, and in the recessed portion 452 of the silicon oxide layer 119, via the opening op2. A film thickness “b” of the silicon nitride layer 131 is formed so as to be smaller than the size “a” of the level difference of the recessed portion 452 and the protruding portion 451.

Then, the process described with reference to FIG. 17 and subsequent processes, of the method of manufacturing according to the first embodiment, are performed, whereby the nonvolatile semiconductor memory device according to the present embodiment can be manufactured.

### Third Embodiment

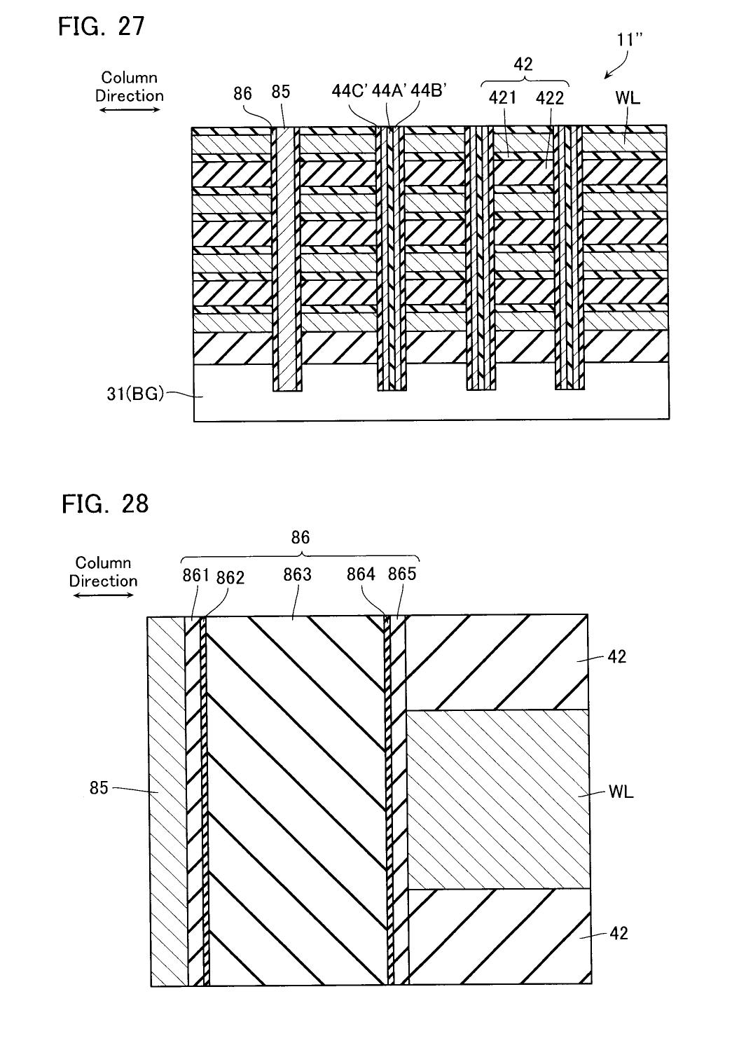

Next, a configuration of a nonvolatile semiconductor memory device according to a third embodiment will be described with reference to FIGS. 27 and 28. FIGS. 27 and 28 are cross-sectional views for explaining the configuration of the nonvolatile semiconductor memory device according to the third embodiment. Note that below, similar configurations to those of the first embodiment are assigned with similar reference symbols to those assigned in the first embodiment, and descriptions thereof will be omitted.

As shown in FIGS. 4 and 19, the memory core layer 44A, the memory semiconductor layer 44B, and the memory gate insulating layer 44C according to the first and second embodiments include the pair of columnar layers 447 extending in a direction perpendicular to the substrate 20, and the coupling layer 448 that couples lower ends of the pair of columnar layers 447, and are formed in a U shape as viewed from the row direction.

In contrast, as shown in FIG. 27, a memory core layer 44A′, a memory semiconductor layer 44B′, and a memory gate insulating layer 44C′ according to the present embodiment are each formed in a column shape. Furthermore, the nonvolatile semiconductor memory device according to the present embodiment includes a source wiring line portion 85 formed so as to penetrate the stacked plurality of word lines WL and inter-layer insulating layers 42, and an inter-wiring line insulating layer 86 covering a periphery of the source wiring line portion 85. The source wiring line portion 85 has one end connected to one end of the memory semiconductor layer 44B′ via the conductive layer 31, and the other end connected to the source line SL (FIG. 2).

Furthermore, as shown in FIG. 28, the inter-wiring line insulating layer 86 is configured comprising: a silicon nitride layer 861 covering the periphery of the source wiring line portion 85; a metal oxide layer 862 covering a periphery of the silicon nitride layer 861; a silicon oxide layer 863 covering a periphery of the metal oxide layer 862; a metal oxide layer 864 covering a periphery of the silicon oxide layer 863; and a silicon nitride layer 865 covering a periphery of the metal oxide layer 864. The metal oxide layers 862 and 864 are formed by a metal oxide of the likes of an aluminum oxide (AlOₓ) such as alumina (Al₂O₃), a hafnium oxide (HfOₓ), or a titanium oxide (TiOₓ), for example. Moreover, a film thickness of the metal oxide layers 862 and 864 is 1 nm or less, and preferably 0.1 nm to 0.5 nm.

In the nonvolatile semiconductor memory device according to the present embodiment, insulation properties between the word line WL and the source wiring line portion 85 are improved. Therefore, it is possible to achieve miniaturization of the nonvolatile semiconductor memory device while maintaining insulation properties between the word line WL and the source wiring line portion 85.

Note that in the inter-wiring line insulating layer 86 according to the present embodiment, the metal oxide layers 862 and 864 and the silicon nitride layers 861 and 865 are provided on both of an inner peripheral surface and an outer peripheral surface of the silicon oxide layer 863. However, it is also possible for the metal oxide layer 862 and silicon nitride layer 861 to be provided on only the inner peripheral surface, or for the metal oxide layer 864 and silicon nitride layer 865 to be provided on only the outer peripheral surface, for example.

Note that the inter-layer insulating layer 42 according to the present embodiment may either be configured similarly to those of the first and second embodiments, or may adopt another configuration.

### Others

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device, comprising:
a plurality of conductive layers stacked in a first direction via an inter-layer insulating layer;
a semiconductor layer having the first direction as a longer direction;
a tunnel insulating layer contacting a side surface of the semiconductor layer;
a charge accumulation layer contacting aside surface of the tunnel insulating layer; and
a block insulating layer contacting a side surface of the charge accumulation layer,
the inter-layer insulating layer comprising:
a first silicon oxide layer;
a first metal oxide layer formed on a first surface facing the conductive layer, of the first silicon oxide layer; and
a first silicon nitride layer formed on the first surface via the first metal oxide layer.

2. The nonvolatile semiconductor memory device according to claim 1, wherein
the inter-layer insulating layer further comprises:
a second metal oxide layer formed on a second surface different from the first surface, of the first silicon oxide layer; and
a second silicon nitride layer formed on the second surface via the second metal oxide layer.

3. The nonvolatile semiconductor memory device according to claim 1, wherein
the inter-layer insulating layer further comprises a third silicon nitride layer contacting a side surface of the block insulating layer, and
the first metal oxide layer
contacts a surface facing the semiconductor layer, of the first silicon oxide layer, and
contacts the third silicon nitride layer.

4. The nonvolatile semiconductor memory device according to claim 1, further comprising
a fourth silicon nitride layer contacting a portion facing the conductive layer, of the block insulating layer, wherein
a recessed portion which is more recessed compared to the portion facing the conductive layer is formed in a portion facing the inter-layer insulating layer, of the block insulating layer,
a protruding portion which protrudes more compared to the recessed portion is formed in the portion facing the conductive layer, of the block insulating layer, and
the recessed portion of the block insulating layer contacts the inter-layer insulating layer.

5. The nonvolatile semiconductor memory device according to claim 4, wherein
the plurality of conductive layers include boron.

6. The nonvolatile semiconductor memory device according to claim 4, wherein
the first silicon nitride layer is formed also between the first silicon oxide layer and the recessed portion of the block insulating layer, and
a level difference formed by the recessed portion and the protruding portion of the block insulating layer is larger than a film thickness of the first silicon nitride layer.

7. The nonvolatile semiconductor memory device according to claim 1, wherein
the first metal oxide layer is configured from aluminum oxide.

8. The nonvolatile semiconductor memory device according to claim 7, wherein
a film thickness of the first metal oxide layer is 0.1 nm to 0.5 nm.

9. The nonvolatile semiconductor memory device according to claim 2, wherein
the second metal oxide layer is configured from aluminum oxide.

10. The nonvolatile semiconductor memory device according to claim 9, wherein
a film thickness of the second metal oxide layer is 0.1 nm to 0.5 nm.

11. A nonvolatile semiconductor memory device, comprising:
a plurality of conductive layers stacked via an inter-layer insulating layer;
a semiconductor layer penetrating the conductive layer and the inter-layer insulating layer;
a tunnel insulating layer covering the semiconductor layer;
a charge accumulation layer covering the tunnel insulating layer;
a block insulating layer covering the charge accumulation layer;
a vertical wiring line layer penetrating the conductive layer and the inter-layer insulating layer and electrically connected to the semiconductor layer at one end thereof; and
an inter-wiring line insulating layer formed between the plurality of conductive layers and the vertical wiring line layer,
the inter-wiring line insulating layer comprising:
a second silicon oxide layer;
a third metal oxide layer formed on a certain surface of the second silicon oxide layer; and
a fifth silicon nitride layer formed on the certain surface of the second silicon oxide layer via the third metal oxide layer.

12. The nonvolatile semiconductor memory device according to claim 11, wherein
the inter-wiring line insulating layer further comprises:
a fourth metal oxide layer formed on another surface different from the certain surface, of the second silicon oxide layer; and
a sixth silicon nitride layer formed on the another surface of the second silicon oxide layer via the fourth metal oxide layer.

13. The nonvolatile semiconductor memory device according to claim 11, wherein
the third metal oxide layer is configured from aluminum oxide.

14. The nonvolatile semiconductor memory device according to claim 13, wherein
a film thickness of the third metal oxide layer is 0.1 nm to 0.5 nm.

15. The nonvolatile semiconductor memory device according to claim 12, wherein
the fourth metal oxide layer is configured from aluminum oxide.

16. The nonvolatile semiconductor memory device according to claim 15, wherein
a film thickness of the fourth metal oxide layer is 0.1 nm to 0.5 nm.
